(19) United States
(12) Patent Application Publication
(10) Pub. No.: US 2009/0257187 A1
(43) Pub. Date: Oct. 15, 2009

(54) Information Handling System with Chassis Design for Storage Device Access

(75) Inventors: R. Steven Mills, Cedar Park, TX (US); Ty R. Schmitt, Round Rock, TX (US); Jimmy D. Pike, Georgetown, TX (US); Joseph A. Vivio, Santa Rosa, CA (US)

Correspondence Address: BAKER BOTTS, LLP, 910 LOUISIANA, HOUSTON, TX, 77002-4995, US

(73) Assignee: DELL PRODUCTS L.P.

(21) Appl. No.: 12/101,534

(22) Filed: Apr. 11, 2008

(51) Int. Cl. H05K 7/00

(52) U.S. Cl. 361/679.33; 361/679.02

(57) ABSTRACT

A design for an information handling system and the chassis of an information handling system is disclosed in which an array of storage devices is included at the front and rear sides of the chassis. Each array of storage devices may include a number of columns and each column may include a number of storage devices. The power supply of the information handling system of the present disclosure is located within the interior of the information handling system. The placement of the power supply in the interior of the information handling system allows an array of storage devices to be located at both the front and rear sides of the chassis. Either the front or rear of the information handling system may include a connection point for data or power connections for the information handling system.

### TECHNICAL FIELD

The present disclosure relates generally to computer systems and information handling systems, and, more particularly, to an information handling system with a chassis design for storage device access in the front and rear of the information handling system.

### BACKGROUND

As the value and use of information continues to increase, individuals and businesses seek additional ways to process and store information. One option available to these users is an information handling system. An information handling system generally processes, compiles, stores, and/or communicates information or data for business, personal, or other purposes thereby allowing users to take advantage of the value of the information. Because technology and information handling needs and requirements vary between different users or applications, information handling systems may vary with respect to the type of information handled; the methods for handling the information; the methods for processing, storing or communicating the information; the amount of information processed, stored, or communicated; and the speed and efficiency with which the information is processed, stored, or communicated. The variations in information handling systems allow for information handling systems to be general or configured for a specific user or specific use such as financial transaction processing, airline reservations, enterprise data storage, or global communications. In addition, information handling systems may include or comprise a variety of hardware and software components that may be configured to process, store, and communicate information and may include one or more computer systems, data storage systems, and networking systems.

The components of an information handling system are typically housed within a chassis. The chassis of an information handling system acts as the frame of the system and determines, at least in part, where the components of the information handling system are spatially arranged in the information handling system. In a typical server computer, the chassis of the computer system includes slots for a series of removable hard disk drives in the front of the server computer. In a 3U chassis, for example, as many as fourteen 3.5″ hard disk drives may be included in the server computer. Thus, in a 42U rack, 196 hard disk drives 3.5″ hard disk drives may be included in the fourteen server computers in the rack.

Racks of servers are housed in a room that is known as a data center or server room. A typical server room will include rows of racks. One difficulty of data centers is the heat generated by the multiple server computers in the data center. Excessive heat leads to high cooling costs for a data center and can result in the degradation in the performance of the computer systems of the rack or data center. In some cases, however, the operation of the data center will over-compensate for the heating effects of the server computers, supplying cooling air to the data center in a manner that is unnecessary. As a result, some data centers operate in a manner that is not optimum, as the data center include sufficient cooling power to accommodate server systems that have higher computing characteristics, including faster computing speeds and additional storage capacities. A typical rack, however, includes server computers that have a chassis design that only accommodates a fixed number of hard disk drives in the rack, despite the availability of a cooling environment in the data center that can accommodate a server computer having a greater number of hard disk drives.

### SUMMARY

In accordance with the present disclosure, a design for an information handling system and the chassis of an information handling system is disclosed in which an array of storage devices are included at the front and rear sides of the chassis. Each array of storage devices may include a number of columns and each column may include a number of storage devices. The power supply of the information handling system of the present disclosure is located within the interior of the information handling system. The placement of the power supply in the interior of the information handling system allows an array of storage devices to be located at both the front and rear sides of the chassis. Either the front or rear of the information handling system may include a connection point for data or power connections for the information handling system.

The information handling system described herein is technically advantageous because the placement of a storage device array at both the front and rear of the information handling system increases the density of storage devices in the server system. The increased density of storage devices may more effectively use the power and thermal capacity of the data room that houses the information handling system. In addition, the placement of a storage device array at both the front and rear of the information handling system allows for the placement of the information handling system in a rack that provides for access to the system at both the front and rear of the system. Other technical advantages will be apparent to those of ordinary skill in the art in view of the following specification, claims, and drawings.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is a front pictorial view of an information handling system; and

FIG. 2 is a rear pictorial view of an information handling system.

### DETAILED DESCRIPTION

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communication with external devices as well as various input and output (I/O) devices, such as a keyboard, a mouse, and a video display. The information handling system may also include one or more buses operable to transmit communications between the various hardware components.

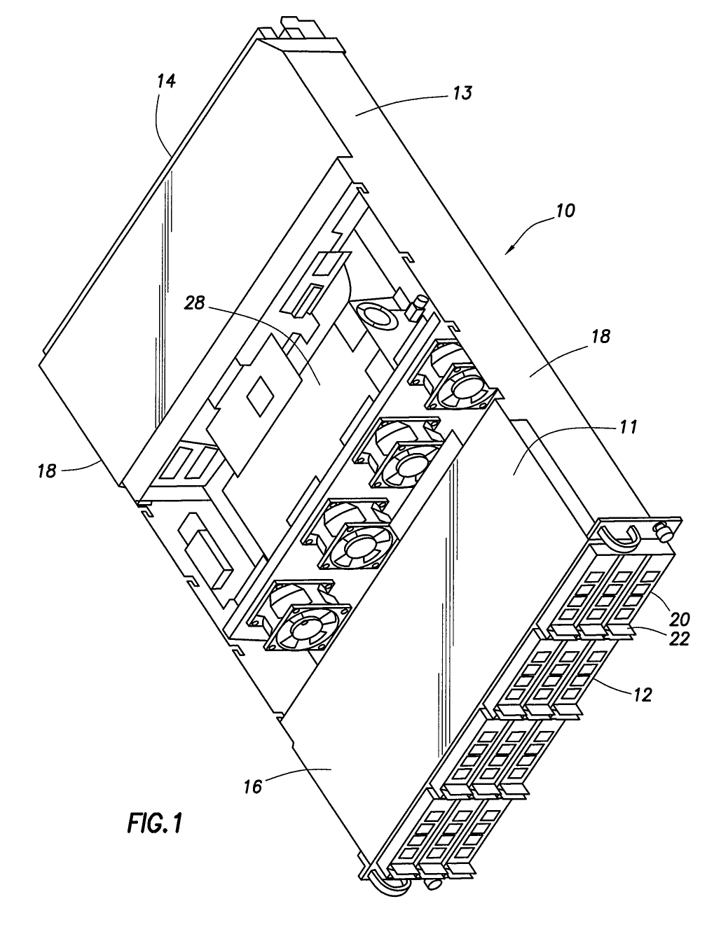

Shown in FIG. 1 is a front pictorial view of an information handling system or computing system, which is indicated generally at 10. Information handling system 10 may also be referred to herein as a server system. The diagram of FIG. 1 is shown with the top surface 11 of the server system being partially removed so that the interior of the server system is shown. Server system 10 includes a chassis 13 that is formed by a frame, which is typically made of metal or plastic. The chassis frame includes a front 12, a back 14, a top 16, two sides 18, and a bottom (not shown). The front 12 of the frame is opposite the back 14 of the frame. Server system 10 also includes a processor and memory. Front 12 includes an array of storage devices. In the example of FIG. 1, the storage devices are hard disk drives. Although the following disclosure is described with reference to hard disk drives, it should be appreciated that any storage device, including tape drives, optical drives, and solid state drives, may be employed in the chassis design that is disclosed herein.

The array 15 of hard disk drives that are arranged four columns of hard disk drives, with three hard disk drives in each column. Each hard disk drive 20 is enclosed in a hard disk drive carrier 22. Each hard disk drive carrier may include a handle that pivots outward. The pivoting of the handle of the carrier causes the hard disk drive carrier to be loosened from its mechanical fitting within the chassis of the computer system and allows the carrier to pulled from the its housing in the chassis of the computer system.

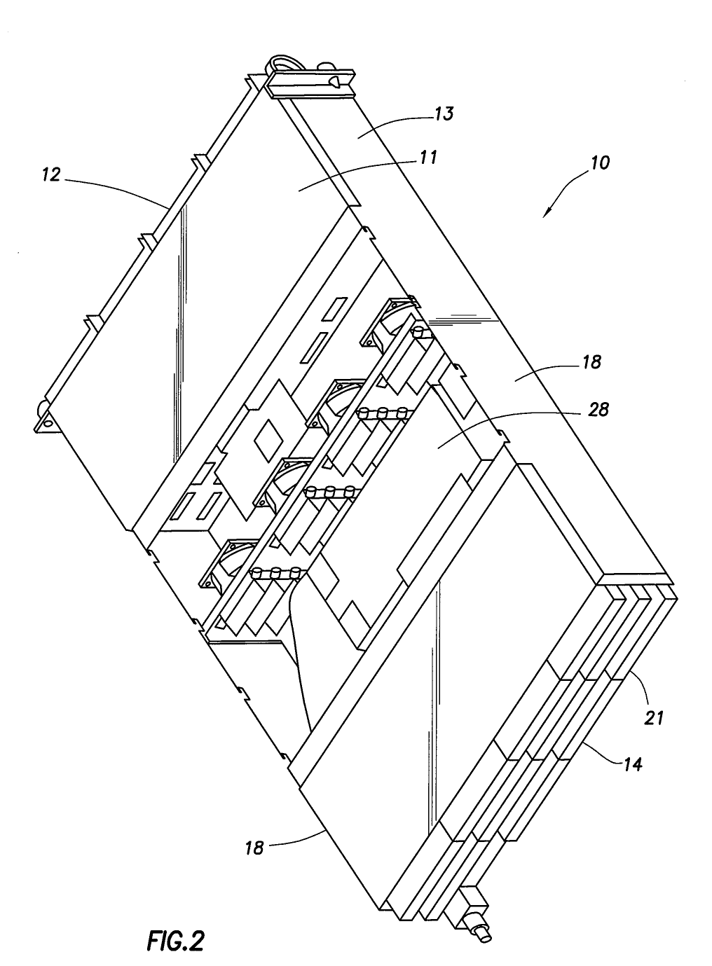

FIG. 2 is a rear pictorial view of server system 10. The back of the server system is shown at 14. Like the front of the server system, the back 14 of the server system includes an array of hard disk drives that are arranged as four columns of hard disk drives. In the example of FIG. 2, the hard disk drives are shown as slots 21, although each slot could be populated with a hard disk drive 20 and carrier 22 as is indicated in the front of server system 10. The first column includes only two hard disk drives, as compared to three hard disk drives in each of the other columns.

In place of the third hard disk drive in the first column, computer system 10 includes one or more connection ports 26 coupled to a connection plate. The connection plate may include a set of data connections, such as a USB port or network connections, or a set of power connections, such as the power plug of the server system. The connection plate may have a size and configuration that is the same as an unpopulated hard drive bay. The electronics for the various power and data ports are included in a bracket in the connection plate that is slid into and out of the unpopulated hard drive bay, thereby allowing for easy service and configuration of the server system. In the example of FIGS. 1 and 2, the server system 10 is a 2U server system that can accommodate three hard disk drives in each column. In the example of FIG. 2, considering that one hard disk drive slot is reserved for a set of connections, twenty-three individual hard disk drives can be included in the server system. Thus, in a 42U rack, 483 individual hard disk drives can be included among the 21 server systems in the rack.

To accommodate the addition of 11 hard disk drives to the rear of the server system, the power supply of the server system, which is sometimes placed within the chassis and adjacent to the rear of the server system near the power plug, is positioned within the interior of the server system. In the example of FIGS. 1 and 2, the power supply is indicated at 28 and is included in the interior of the chassis of the server system to accommodate a set of hard disk drives in the interior of the chassis adjacent the back 14 of the server system. The placement of the power supply in the interior of the server system allows for the placement of an array of hard disk drives in the rear or back of the server system. Although a single power supply is shown in FIGS. 1 and 2, it should be understood that chassis design described herein may include multiple power supplies, which may be arranged as redundant power supplies.

The configuration of the chassis of the server system that is described herein has several advantages. The chassis design places more hard disk drives within a single chassis. Because more hard disk drives are included within a single chassis, more hard disk drives may be included within a single rack of server systems, thereby increasing the density of hard disk drives included within a single rack and included within a server room. In a data room that over-compensates for the heating effects of the server systems in the room, the higher density of hard disk drives in the chassis and racks of the present invention can be accommodated and not exceed the thermal capacity of the data room. The placement of the power supply to the interior of the chassis allows for a set of hard disk drives to be arranged along the back of the chassis. The placement of hard disk drives on both the front and the rear of the chassis allows the chassis to be placed in a rack that can be accessed from both the front and the back of the rack.

The chassis design that is disclosed herein is not limited in its application to servers having a height of 2U. Rather, the chassis design described herein may be any other height. Although the present disclosure has been described in detail, it should be understood that various changes, substitutions, and alterations can be made hereto without departing from the spirit and the scope of the invention as defined by the appended claims.

What is claimed is:

1. A chassis for an information handling system, comprising:
a frame, wherein the frame includes a front and a back and wherein the front and the back are on opposite sides of the frame.
an array of storage devices adjacent to the front of the frame; and
an array of storage devices adjacent to the back of the frame.

1. The chassis of claim 1, wherein the storage devices comprise hard disk drives.

3. The chassis of claim 2, wherein the array of hard disk drives adjacent to the front of the frame includes multiple columns of hard disk drives.

4. The rack system of claim 2, wherein the array of hard disk drives adjacent to the back of the frame includes multiple columns of hard disk drives.

5. The rack system of claim 4, wherein the array of hard disk drives adjacent to the back of the frame includes a column that has fewer hard disk drives than are included in the other columns.

6. The rack system of claim 2, wherein the chassis has a height of 2U.

7. The rack system of claim 6, wherein the array of hard disk drives adjacent to the front of the frame includes multiple columns of hard disk drives.

8. The rack system of claim 7, wherein the array includes four columns and wherein each column includes three hard disk drives.

9. The rack system of claim 6, wherein the array of hard disk drives adjacent to the back of the frame includes multiple columns of hard disk drives.

10. The rack system of claim 9,
wherein the array includes four columns;
wherein one of the columns includes only two hard disk drives and wherein the column that includes only two hard disk drives includes a connection port that has the size and configuration of a hard drive bay.

11. An information handing system, comprising:
a processor;
memory;
a chassis housing the processor and the memory, wherein the chassis includes a frame that has a front and a back;
a first array of storage devices proximate the front of the chassis;
a second array of storage devices proximate the back of the frame; and
a power supply in the interior of the chassis between the first array of hard disk storage devices and the second array of storage devices.

12. The information handling system of claim 11, wherein the storage devices are hard disk drives.

13. The information handling system of claim 12, wherein each array of hard disk drives includes multiple columns of hard disk drives.

14. The information handling system of claim 13, wherein the array of hard disk drives proximate the back of the chassis includes a column that has fewer hard disk drives than are included in the other columns of the array.

15. The information handling system of claim 12, wherein each column includes three hard disk drives.

16. The rack housing multiple computer systems of claim 12, wherein the array includes four columns.

17. A computer system, comprising:
a chassis having a front side and a back side;
a processor;
a memory coupled to the processor, wherein the processor and the memory are included with in the chassis;
a first array of hard disk drives proximate the front side of the of the chassis;
a second array of hard disk drives proximate the back side of the chassis; and
a power supply disposed in the interior of the chassis and between the first array of hard disk drives and the second array of hard disk drives.

18. The computer system of claim 17, wherein the second array of hard disk drives includes a connection plate for receiving power and data connections for the computer system.

19. The computer system of claim 16, wherein the connection plate has the size and configuration of an empty hard drive bay.

20. The computer system of claim 16, wherein each array includes multiple columns of hard disk drives and wherein each column includes multiple hard disk drives.
